(19) United States
(12) Patent Application Publication
(10) Pub. No.: US 2002/0129970 A1
(43) Pub. Date: Sep. 19, 2002

(54) Portable electronic medium and manufacturing method thereof

(76) Inventor: Masaru Murohara, Kanagawa-ken (JP)

Correspondence Address: PILLSBURY WINTHROP, LLP, P.O. BOX 10500, MCLEAN, VA, 22102, US

(21) Appl. No.: 09/919,996

(22) Filed: Aug. 2, 2001

(30) Foreign Application Priority Data
Mar. 19, 2001 (JP) 2001-077646

(51) Int. Cl. H05K 1/03

(52) U.S. Cl. 174/255

(57) ABSTRACT

A portable electronic medium includes a circuit substrate of which first surface is exposed to the outside, forming one of the outer surfaces and a second surface provided on the back of the first surface with an electronic part mounted, a terminal portion formed on the first surface of the circuit substrate for exchanging data with outer devices by connecting to them, and a resin layer formed substantially in the same size as the circuit substrate and laminated on the entire surface of the second surface with electronic part mounted thereon.

### CROSS-REFERENCE TO RELATED APPLICATION

This application is based upon and claims the benefit of priority from the prior Japanese Patent Application No. P2001-77646 filed on Mar. 19, 2001; the entire contents of which are incorporated herein by reference.

### BACKGROUND OF THE INVENTION

1. Field of the Invention

The present invention relates to a portable electronic medium comprising a thin memory card, for instance, SD card (Secured Digital memory card), etc. and a portable electronic medium manufacturing method.

2. Description of the Related Art

As a manufacturing method of portable semiconductor devices (for instance, IC cards, etc.) with electronic parts embedded in the card body without vacant space, there is so far available a non-contact IC card manufacturing method as disclosed in Japanese Laid Open Patent Publication No. 01-241486.

On this IC card, a module with IC, cell, etc. mounted on a circuit substrate is housed in a case. Then, a thermosetting resin is poured into the case through a hole provided on the upper case and fills the space in the case, and is then hardened by heating so that the case and the module are combined solidly.

The IC cards manufactured according to a conventional manufacturing technology described above are in a structure with the outside covered by the upper and lower cases. As a result, the thickness of this IC card became thick and it was difficult to make it thin in thickness.

### BRIEF SUMMARY OF THE INVENTION

The present invention has been made in view of the above circumstances and it is an object to provide a portable electronic medium made thinner in thickness and a manufacturing method of a portable electronic medium.

According to the present invention, a portable electronic medium is provided. This medium comprises: a circuit substrate comprising a first surface that is exposed to the outside, forming one of the outer surfaces and a second surface provided at the back of the first surface with an electronic part mounted; a terminal portion formed on the first surface to make the data exchange by connecting to an external device; and a resin layer formed substantially in the same size as the circuit substrate, laminated on the entire second surface with the electronic part mounted, forming another outer surface.

Further, according to the present invention, a portable electronic medium manufacturing method is provided. This medium has a circuit substrate comprising a first surface exposed to the outside, forming one outer surface and a second surface provided on the back of the first surface with electronic parts mounted, and plural terminals formed on the first surface of the circuit substrate for making the data exchange by connecting to external devices. This manufacturing method comprises: supplying fused resin for covering the entirety of the electronic parts and the second surface; and hardening the supplied resin.

### BRIEF DESCRIPTION OF THE DRAWINGS

FIG. 1A and FIG. 1B show the external appearance of a portable electronic medium in the embodiments of the present invention, FIG. 1A is a plan view showing the first surface of the portable electronic medium, and FIG. 1B is a plan view showing the second surface of the portable electronic medium;

FIG. 2 is a front view of the portable electronic medium shown in FIGS. 1A and 1B;

FIG. 3 is a plan view showing a substrate with electronic parts arranged on the portable electronic medium shown in FIGS. 1A and 1B;

FIG. 4 is a plan view showing a clustered substrate that is used when plural portable electronic media are simultaneously formed in another embodiment of the present invention;

FIG. 5 is a plan view further showing a clustered substrate that is used when plural portable electronic medium are simultaneously formed in another embodiment of the present invention;

FIGS. 6A-6D are sectional views showing a portable electronic medium manufacturing method in the embodiment of the present invention;

FIGS. 7A and 7B are sectional views showing a cutting process in the portable electronic medium manufacturing method in the embodiment of the present invention;

FIGS. 8A-8E are sectional views showing a portable electronic medium manufacturing method in another embodiment of the present invention;

FIGS. 9A-9D are sectional views showing a portable electronic medium manufacturing method in another embodiment of the present invention;

FIGS. 10A and 10B are sectional views showing a process for further elongating a second resin in the manufacturing method shown in FIGS. 9A-9D;

FIGS. 11A and 11B are sectional views showing the cutting process;

FIGS. 12A-12D and 13A-13C are sectional view showing the portable electronic medium in another embodiment of the present invention;

FIGS. 14A-14E are sectional views further showing the portable electronic medium manufacturing method in another embodiment of the present invention;

FIGS. 15A and 15B are sectional views showing the cutting process;

FIGS. 16A-16D are sectional views showing the portable electronic medium manufacturing method of the portable electronic medium in another embodiment of the present invention;

FIGS. 17A-17C are sectional views further showing the portable electronic medium manufacturing method in another embodiment of the present invention;

FIG. 18 is a sectional view showing the portable electronic medium manufacturing method in another embodiment of the present invention;

FIG. 19 is a sectional view further showing the portable electronic medium manufacturing method in another embodiment of the present invention;

FIGS. 20A and 20B are sectional views showing the portable electronic medium manufacturing method in another embodiment of the present invention;

FIG. 21 is a sectional view for explaining the external appearance of the portable electronic medium in the final shape in the embodiment of the present invention; FIG. 22 is a sectional view for explaining the external appearance of the portable electronic medium in the final shape in the embodiment of the present invention;

FIG. 23 is a sectional view for explaining the external appearance of the portable electronic medium in the final shape in the embodiment of the present invention;

FIG. 24 is a sectional view for explaining the external appearance of the portable electronic medium in the final shape in the embodiment of the present invention; and

FIGS. 25A-25C are sectional views further showing the portable electronic medium manufacturing method in another embodiment of the present invention.

### DETAILED DESCRIPTION OF THE INVENTION

Preferred embodiments of the present invention will be described below with reference to drawings.

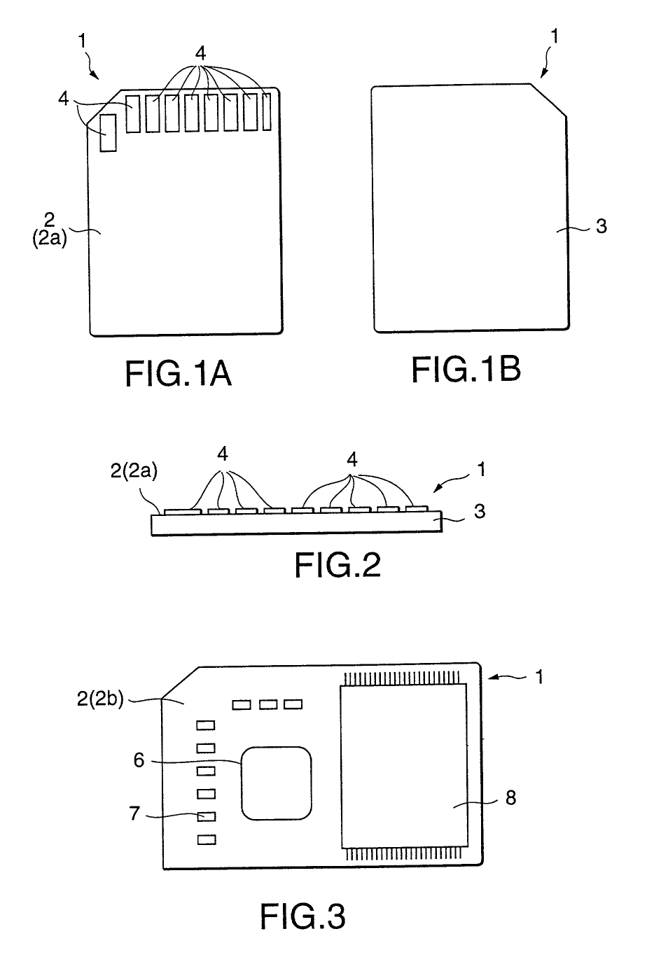

FIGS. 1A, 1B and 2 show thin type memory cards, for instance, SD cards, etc. as a portable electronic medium 1. The main body of the electronic medium 1 comprises a substrate 2 with such electronic component parts as memory, etc. mounted shown in FIG. 1A and a curing resin layer 3 shown in FIG. 1B. A first surface 2a exposed to the outside of the substrate 2 of the main body of the electronic medium 1 is formed nearly flat as electronic parts, etc. are not mounted.

Further, on the upper one end of the first surface 2a exposed to the outside of the substrate 2, plural contact pads 4 are arranged in a row as contact terminals at prescribed intervals to expose to the outside. The contact pads 4 are provided for supplying supply and exchanging data with an external device.

As shown in FIG. 3, the substrate 2 is formed with a 0.2 mm thick glass epoxy plate. On a second surface 2b that is sealed with resin, for instance, a control IC 6 for controlling the entire electrode medium 1 and a memory 8 for storing various kinds of data, a capacitor 7 and other chip parts are mounted at prescribed intervals as electronic parts.

Plural electronic parts mounted on the second surface 2b are in different heights and installed at different intervals, respectively.

Next, a manufacturing method of the electric medium 1 will be described. Further, in this embodiment, a method for manufacturing the electronic medium 1 using a clustered substrate 20 comprising the substrates 2 for 8 units of the electronic medium 1 will be described.

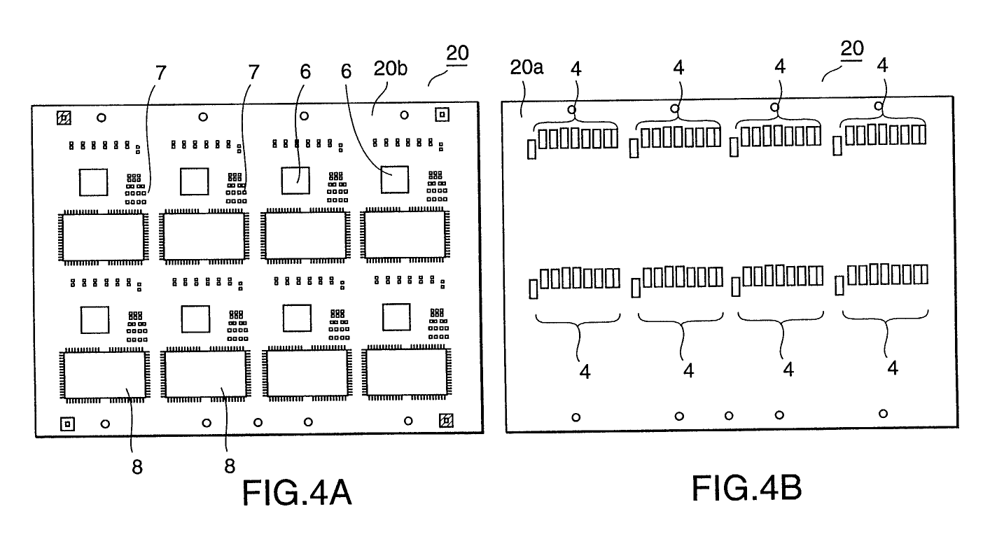

The substrate 20 shown in FIGS. 4A and 4B is a 0.2 mm thick glass epoxy plate in a size large enough for manufacturing 8 units of the electronic medium 1. The substrate 20 comprises the second surface 20b on which various kinds of electronic parts are mounted as shown in FIG. 4A and the first surface 20a with the contact pads 4 formed, exposing to the outside and serving as an armored plate as shown in FIG. 4B.

The second surface 20b has chip capacitors, chip resistors 7 and memories 8 soldered at prescribed positions and the control ICs 6 mounted by the wire bonding.

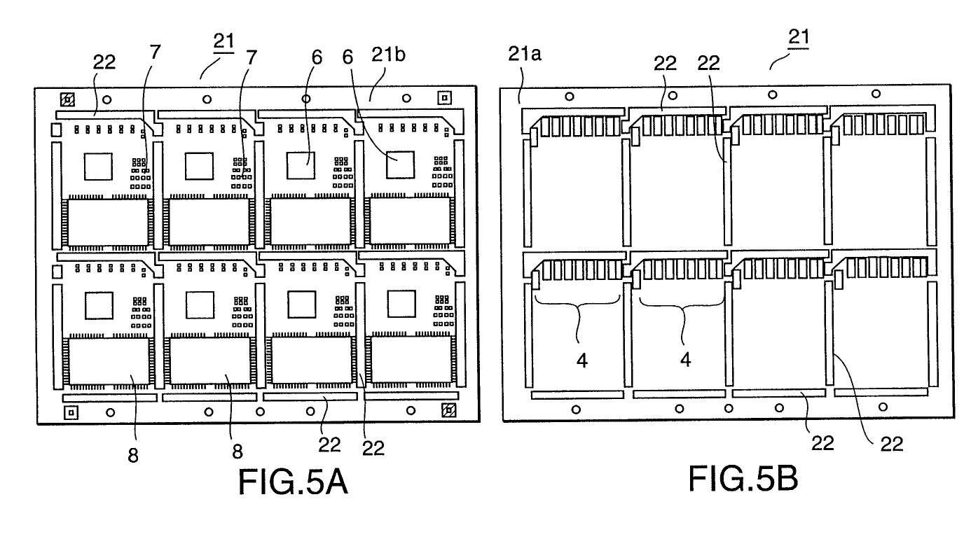

A substrate 21 shown in FIGS. 5A and 5B is different from the substrate 20 shown in FIGS. 4A and 4B in that slits 22 are formed at points equivalent to the outside of each electronic medium 1 so as to make it easy to cut it after formed. All others are formed similarly and therefore, the explanation will be omitted.

As shown in FIGS. 4A through 5B, when the control ICs 6 are connected by the wire bonding after the electronic parts are soldered on the clustered substrate 20 (or 21), proceeds to the next manufacturing process. As this time, the control IC 6 can be sealed by the resin sealing that is performed in the next step and therefore, the IC chip sealing process can be omitted.

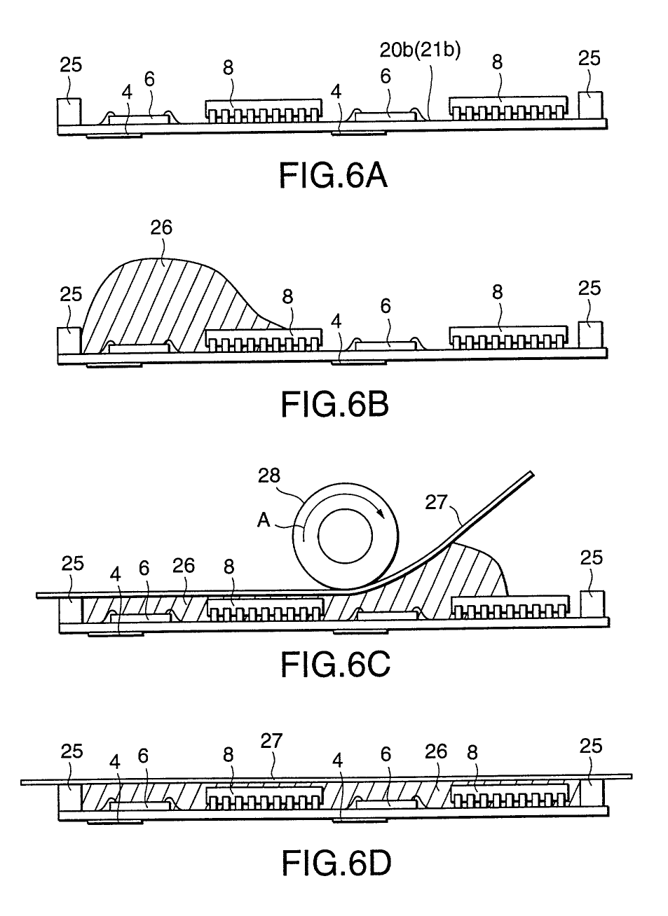

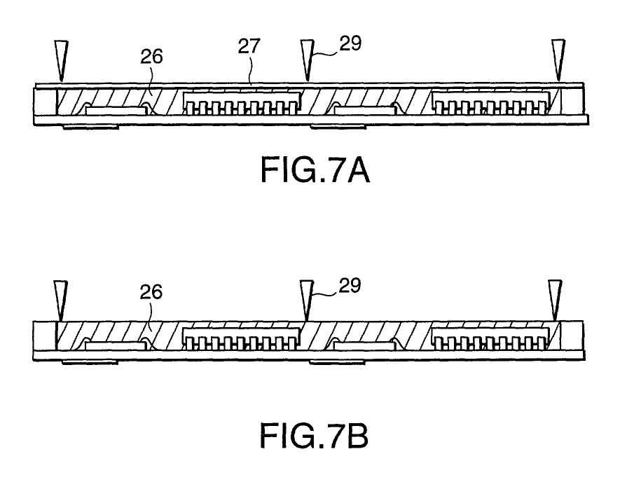

Next, using FIGS. 6A-6D and FIG. 7, an example of a manufacturing method of the electronic medium 1 for the clustered substrate 10 (or 21) with electronic parts mounted will be described.

First, as shown in FIG. 6A, a dam 25 that is formed in the rectangular shape with plastic is bonded on a surface 20b (or 21b) of the clustered substrate 20 (or 21). The thickness of the electronic medium 1 after formed will become the height (thickness) of this dam 25 plus the thickness of the substrate. Accordingly, the dam 25 is formed in the thickness (height) of the thickness of the electronic medium 1 after formed less the thickness of the substrate.

It is considered that the dam 25 is provided only on the periphery of the clustered substrate 20 (or 21) or on the peripheral portion of individual electronic medium 1. In this example, a case to provide the dam 25 only on the periphery of the clustered substrate 20 will be described.

Then, a resin 27 is coated on the second surface 20b of the clustered substrate 20 (or 21) with the dam 25 formed as shown in FIG. 6B. Hereinafter, this resin 26 to be coated will be described using an ultraviolet curing resin in this example. However, even when a thermosetting resin is used, the same purpose and effect can be achieved.

As shown in FIG. 6C, a protective layer, for instance, a 0.1 mm thick transparent sheet 27 is laid on the second surface 20b (or 21b) of the clustered substrate 20 (or 21) coated with the resin 26. The coated resin 26 is elongated to a flat state by rotating a roller 28 on this transparent sheet 27 in the arrow direction A.

The resin 26 thus elongated in the flat state is cured by applying ultraviolet rays as shown in FIG. 6D.

When the resin 26 is cured, the clustered substrate 20 (or 21) is cut in a prescribed shape (the shape of individual electronic medium 1) using a cutter 19, etc. as shown in FIG. 7. Thus, the electronic medium 1 is completed.

FIG. 7A shows one example to complete the electronic medium 1 in the state with the transparent sheet 27 pasted. When the electronic medium 1 is kept in the state with the sheet 27 pasted, it becomes possible to print on the sheet surface and the sheet 27 also can be used to function as a protective layer.

Instead of the above-mentioned transparent sheet 27, a printed sheet may be used. In this case, thermosetting resin is desirable as the resin 26.

FIG. 7B shows one example to complete the electronic medium 1 with the transparent sheet 27 peeled off. When the sheet 27 is peeled off, it becomes possible to form the electronic medium 1 more inner.

On the first surface of the substrate of the electronic medium 1 manufactured according to the method shown in the above embodiment, plural contact terminals are arranged nearly in a row and plated to form one outer surface of the electronic medium 1 as shown in FIGS. 7A and 7B.

On the second surface with electronic parts mounted, a laminated resin layer is formed nearly in the same size as the substrate. This resin layer is preferably formed so as to fill the spaces between electronic parts mounted on the second surface and forms another outer surface of the electronic medium 1.

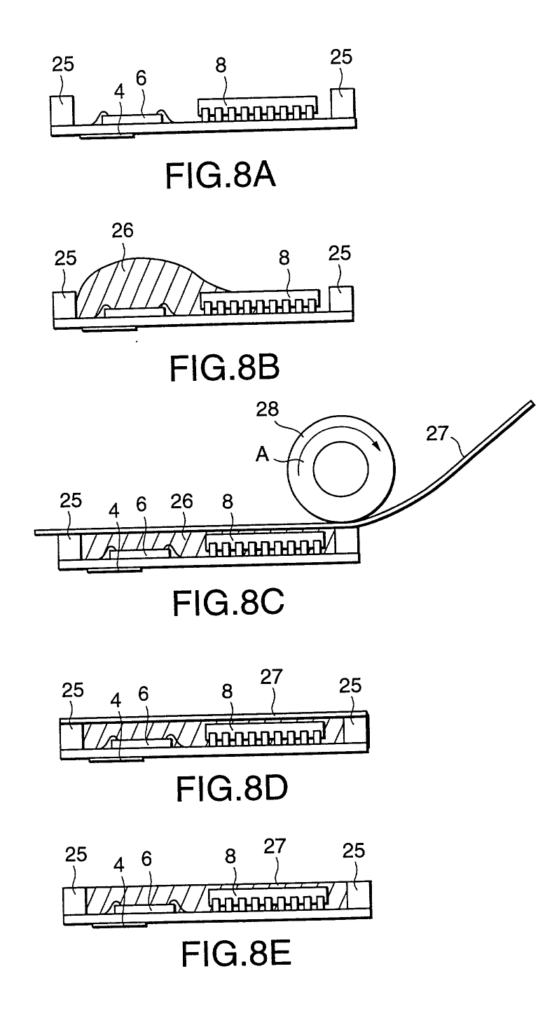

Further, FIGS. 8A-8E show a deformed example of the embodiment explained referring to FIGS. 6A-6D. The embodiments explained referring to FIGS. 6A-6D were explained according to the method for simultaneously manufacturing plural electronic media 1 using a clustered substrate. However, not restricted to this embodiment, when manufacturing a single electronic medium, this method has the same merit and is effective as in the deformed examples shown in FIGS. 8A-8E.

FIGS. 8A-8E differ from FIGS. 6A-6D in that a single electronic media is manufactured and the same portions are assigned with the same reference numerals shown in FIGS. 6A-6D. Further, the finally completed electronic medium may be in the state with a sheet shown in FIG. 8D. In addition, it may be in the state with the sheet peeled off as shown in FIG. 8E. Furthermore, it may be considered to cut the dam 25 to a prescribed size at the periphery of a substrate.

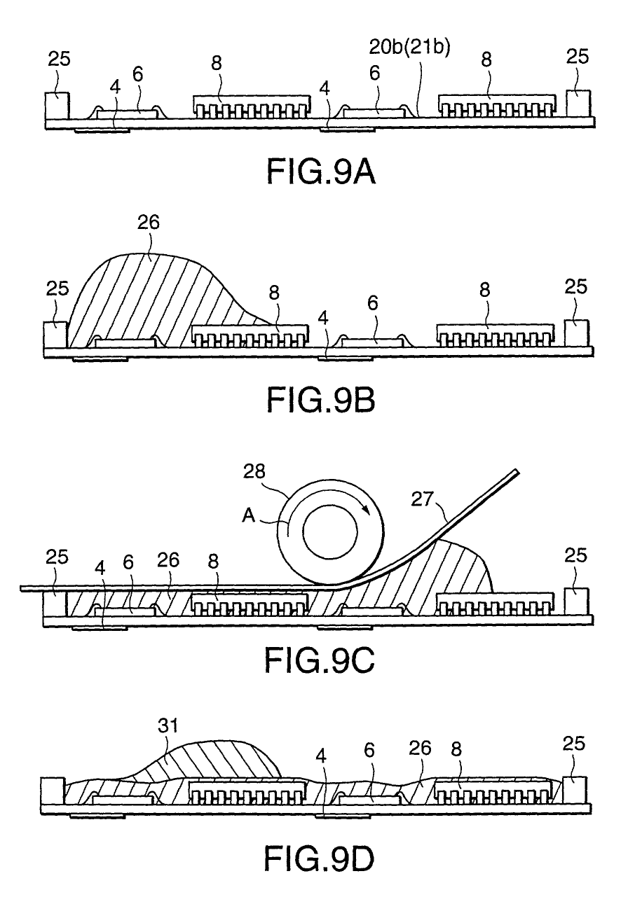

Next, an embodiment of the manufacturing method of the electronic medium 1 for the clustered substrate 20 (or 21) will be described referring to FIGS. 9A-11B.

First, a dam 25 is bonded on the second surface 20b (or 21b) of the clustered substrate 20 (or 21) as shown in FIG. 9A. The thickness of the electronic medium 1 after formed depends on the height (thickness) of this dam and the thickness of the substrate. Accordingly, the dam 25 is formed in a thickness (height) by reducing the thickness of the substrate from the thickness of the electronic medium 1 after formed.

It is considered that the dam 25 is provided on the periphery only of the clustered substrate 20 (or 21) or on the peripheral portion only of the individual electronic medium 1 only. In this embodiment, a case wherein the dam 25 is provided on the periphery only of the clustered substrate 20 (or 21) will be described.

The resin 26 is coated on the second surface 20b (or 21) of the clustered substrate 20 (or 21) on which the dam 25 is formed as shown in FIG. 9B. Hereinafter, in this embodiment, this resin 26 to be coated will be explained using an ultraviolet setting resin. However, the same purpose and effect can be achieved even when a thermosetting resin is used.

Lay a first sheet 27 on the second surface 20b (or 21b) of the clustered substrate 20 (or 21) with the resin 26 coated as shown in FIG. 9C. Elongate the resin 26 by rotating a roller 28 in the arrow direction A on the first sheet 27. Thus, the coated resin 26 is flattened.

Cure the resin 26 by applying ultraviolet rays on the resin 26 prepared in the flat state. At this time, if the surface of the cured resin becomes uneven because of the contraction when curing the resin as shown in FIG. 9D, peel off the first sheet 27 and coat a resin 31 (hereinafter, referred to as a second resin again) again over the resin surface.

At this time, in this embodiment, a resin that has a slightly softer characteristic than the hardness of the formerly coated/cured resin (the first resin) is used for the second resin 31 at this time.

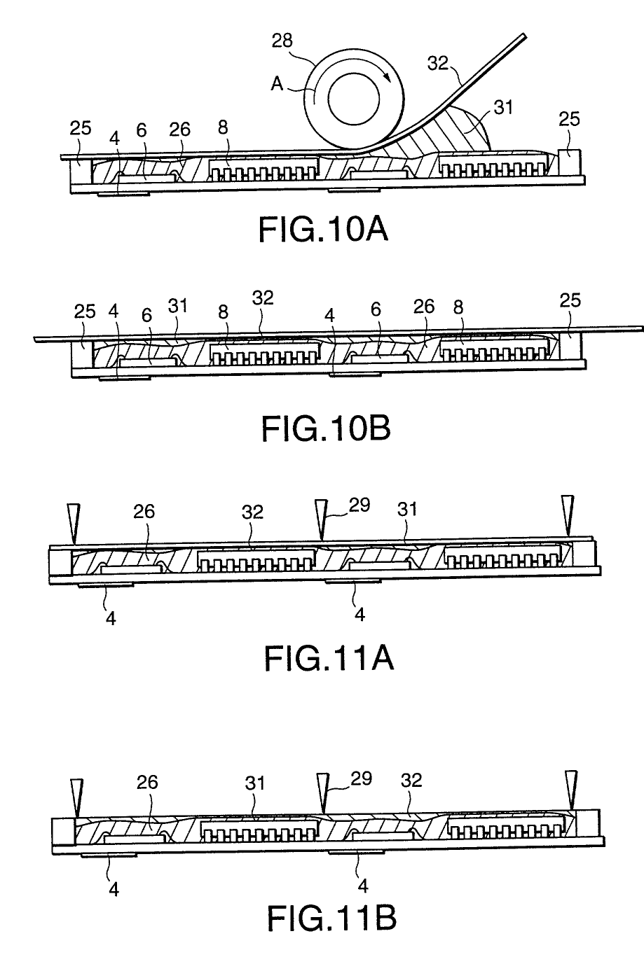

Lay a second sheet 32 on the coated second resin 31 as shown in FIG. 10A. Elongate the second resin 31 by rotating the roller 28 on the second sheet 32 in the arrow direction A. Thus, the coated second resin 31 is flattening.

Cure the second resin 31 by applying ultraviolet rays to the second resin thus prepared in the flat state as shown in FIG. 10B.

When the second resin 31 is thus cured, complete the electronic medium 1 by cutting the clustered substrate 20 (or 21) in the prescribed shape (the shape of individual electronic medium) using the cutter 29, etc.

As shown in FIGS. 11A and 11B, the electronic medium 1 manufactured according to the method shown in the above embodiment has the first surface of the substrate plated to arrange that plural contact pads 4 nearly in a row and formed one outer surface of the electronic medium 1.

Further, a first resin layer is formed in the nearly same size as the substrate and laminated on the second surface with electronic parts mounted. This first resin layer preferably fills the clearances between electronic parts mounted on the second surface.

The surface of the first resin layer will become uneven because of different heights of covering electronic parts thereon when the resin is cured and contracted. A second resin layer is laminated on the first resin layer so as to bury the uneven surface of the first resin layer and forms the other outer surface of the electronic medium 1.

Further, FIG. 11A shows one embodiment to complete the electronic medium 1 in the state with a second sheet 32 pasted. When the second sheet 32 is kept in the pasted state, it becomes possible to apply printing, etc. on the surface of this sheet of the electronic medium 1 and the sheet also functions as a protective layer.

Further, FIG. 11B shows one embodiment to complete the electronic medium 1 with the second sheet 32 peeled off. When the second sheet 32 is peeled off, it becomes possible to form the electronic medium 1 in more thin thickness.

Thus, by coating/filling resin in several times, it becomes possible to make the surface flat even when a rate of shrinkage is different, resulting from a difference in heights of mounted electronic parts. Accordingly, there is also such an effect that the surface can be formed so as to have a uniform strength.

Further, when resin is coated/cured in several times, a new effect can be obtained by changing material (hardness), curing method (heat, ultraviolet rays, etc.), color (transparent, colored such as black, etc.

For instance, when a resin is coated/cured in several times, the lastly coated resin becomes the outer armor of the electronic medium 1. Accordingly, when a relatively hard resin is used for preceding coating/curing (the first resin) and a resin softer than the preceding resin for the last coating (the second resin), it is possible to make a structure capable of absorbing a shock from the outside while keeping its strength.

Further, when an ultraviolet curing resin is used, a transparent sheet is used but when using a thermosetting resin, a sheet color is not specified. Accordingly, when using a transparent resin is used for the preceding coating/curing (the first resin) and a same colored resin as the substrate (e.g., black) for the last coating (the second resin), an electronic medium can be manufactured at a cheap cost.

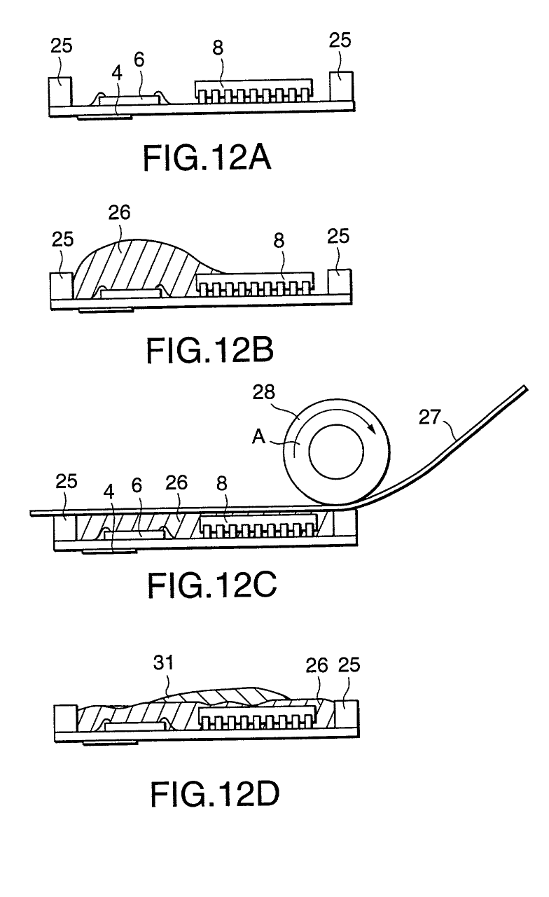

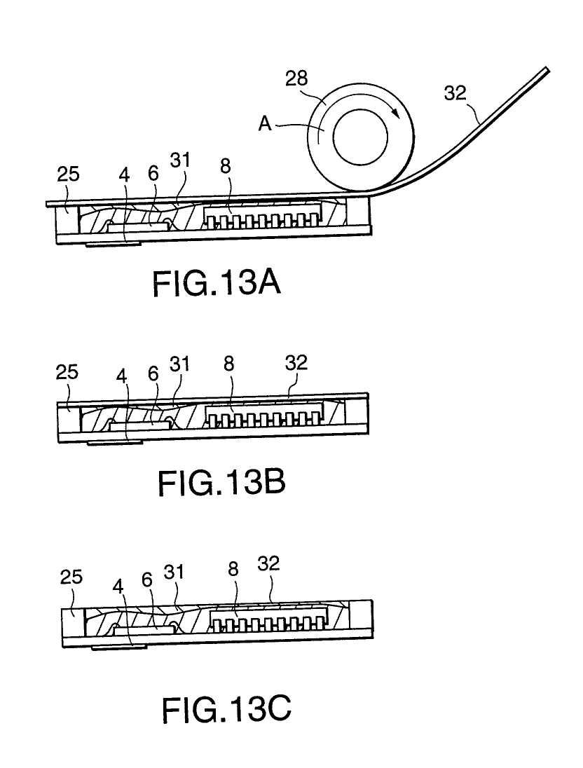

Further, FIGS. 13A-13C show deformed embodiment of what is explained referring to FIGS. 12A-12D. In the embodiment explained referring to FIGS. 10A-11B, the simultaneous manufacturing method of plural electronic media 1 using a clustered substrate was explained. However, not restricted to this, the method has the same merit and is effective as in the deformed examples shown in FIGS. 12A-13C.

Further, what are shown in FIGS. 12A-13C differ from those shown in FIGS. 9A-11B in that only a single electronic medium is manufactured and the same reference numerals as those shown in FIGS. 9A-11B are used for the same parts. Further, the finally completed electronic medium may be in the state with the sheet pasted as shown in FIG. 13B or with the sheet peeled off as shown in FIG. 13C. Furthermore, it is also considered that the dam 25 is cut to a prescribed size at the periphery of the substrate.

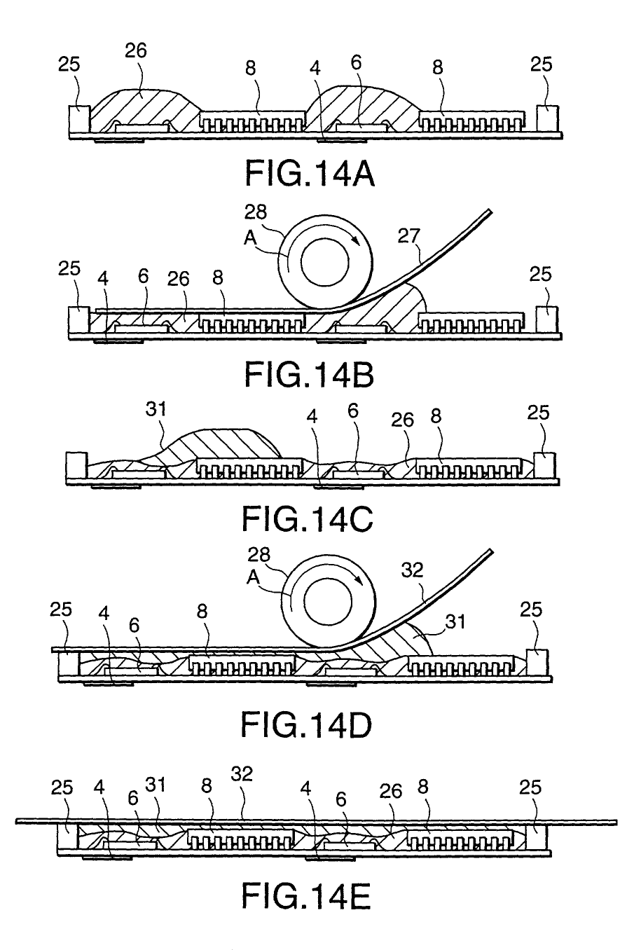

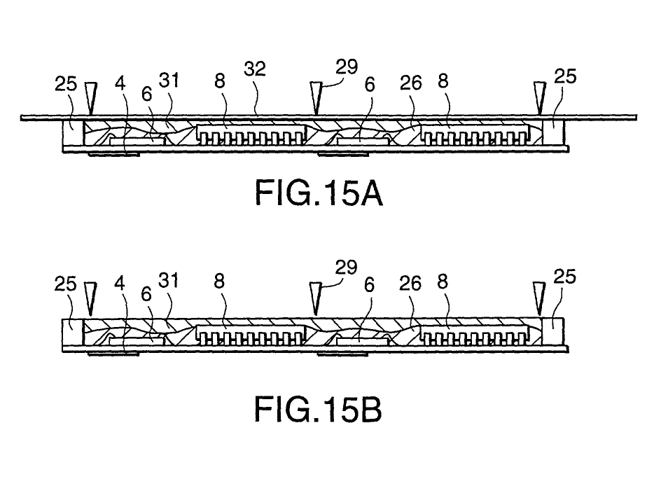

Further, FIGS. 14A-15B show deformed examples of the embodiments of the electronic medium explained referring to FIGS. 9A-11B. In the examples explained referring to FIGS. 9A-11B, the first resin 26 is coated on the overall surface of the second surface 20b (or 21).

On the contrary, in the deformed examples shown in FIGS. 14A-15B, the second resin 31 is coated on the portion without electronic parts mounted and on the electronic parts of low mounting height on the second surface 10b (or 21b).

Accordingly, when the second resin 31 is coated/cured after forming the second surface 20b (or 21b) almost flat with electronic parts in high mounting height and the first resin 26, a rate of shrinkage when the second resin 31 is cured becomes uniform. Accordingly, the surface of the second resin 31 formed on the outer surface exposed to the outside is formed flat without uneven portions.

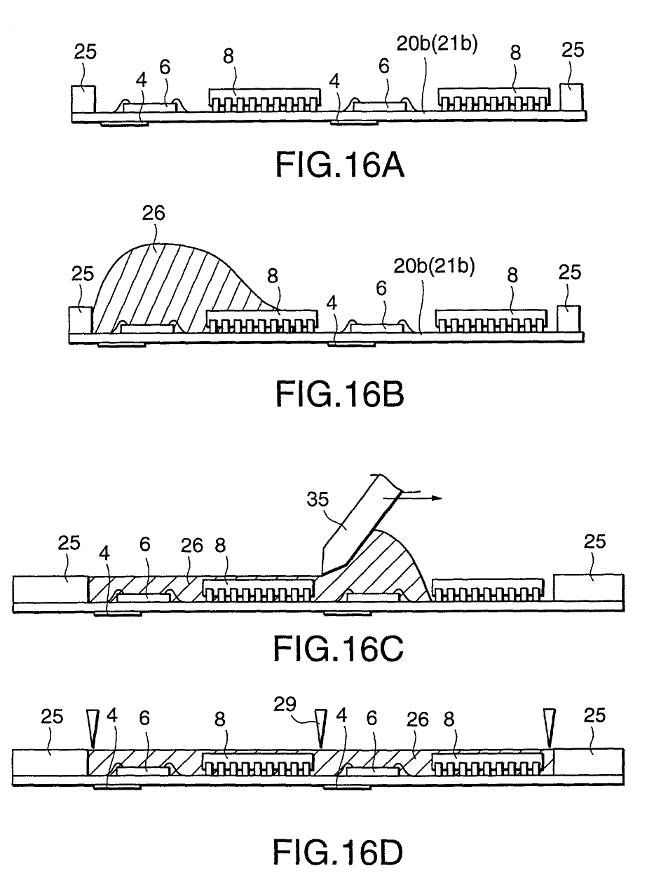

Next, referring to FIGS. 16A-16D, examples of the manufacturing method of the electronic medium 1 on the clustered substrate 10 (or 21) with electronic parts mounted will be explained.

In the embodiments shown in FIGS. 8-10 and 12-14, an example using a roller for making a resin coated on the clustered substrate flat was explained. However, in this example, a resin coated on the clustered substrate is made smooth and flat using a squeegee.

First, the dam 25 is bonded on the second surface 20b (or 21) of the clustered 20 (or 21) as shown in FIG. 16A. The thickness of the electronic medium 1 after formed depends on the height (thickness) of this dam 25 and the thickness of the substrate. Accordingly, the dam 25 is formed in a thickness (height) with the thickness of the substrate deducted from the thickness of the formed electronic medium 1.

It is considered that this dam 25 may be provided only at the periphery of the clustered substrate 20 (or 21) or at the peripheral portion of individual electronic medium 1. In this embodiment, a case wherein the dam 25 is provided at the periphery only of the clustered substrate 20 (or 21) is explained.

Then, coat the resin 26 on the second surface 20b (or 21) of the clustered substrate 20 (or 21) with the dam 25 formed as shown in FIG. 16B. Hereinafter, in this embodiment an ultraviolet curing resin is used for the resin 26 to be coated. However, the same purpose and merit are achieved even when a thermosetting resin is used.

As shown in FIG. 16C, make the coated resin 26 flat using the squeegee 35 so that the resin 26 coated on the second surface 20 (or 21) of the clustered substrate 20 (or 21) becomes the same height as the dam 25.

Apply the ultraviolet rays to the resin 26 that is prepared flat and cure it as shown in FIG. 16D. When the resin 26 is hardened, cut the clustered substrate 20 (or 21) in a prescribed shape (the shape of individual electronic medium 1) with the cutter 29, etc. The electronic medium 1 is thus completed.

In this example, as the resin coated without using a roller and a transparent sheet is made flat, it is possible to manufacture the electronic medium 1 without using an extra sheet.

The first surface of the substrate of the electronic medium 1 manufactured according to the method shown in the embodiment shown in FIGS. 16A-16D has plural contact pads arranged in a row and processed by plating and forms one of the outer surface of the electronic medium 1.

Further, on the second surface with electronic parts mounted, a resin layer laminated thereon is formed nearly in the same size as the substrate. This resin layer is formed preferably to fill the gaps among electronic parts mounted on the second surface and makes another outer surface of the electronic medium 1.

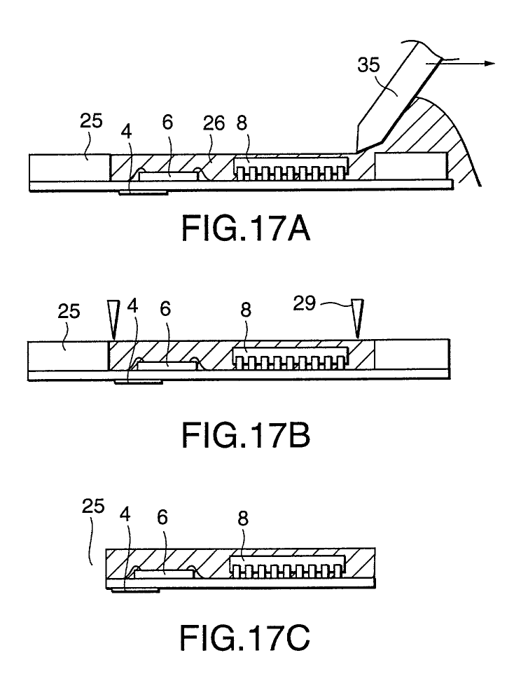

Further, FIGS. 17A-17C show deformed examples of the embodiments shown in FIGS. 16A-16D. The embodiments shown in FIGS. 16A-16C were explained according to the method for simultaneously manufacturing plural electronic media 1 using a clustered substrate. However, not restricted to the simultaneous manufacturing of plural electronic media, this method has the same effect and is effective when manufacturing a single electronic medium as shown in FIGS. 17A-17C.

The embodiments shown in FIGS. 17A-17C differ from those shown in FIGS. 16A-16C in that one electronic medium is manufactured and the same parts are assigned with the same reference numerals used in FIGS. 16A-16C. Further, the finally completed electronic medium may be in such a state that it is cut in a prescribed size in the inside of the dam 25 as shown in FIG. 17B and furthermore, the state leaving the dam 25 may be considered.

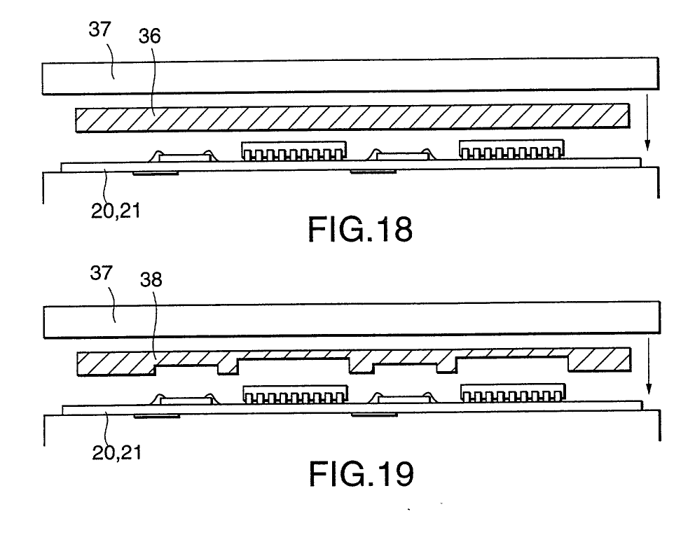

Next, an embodiment of the manufacturing method of the electronic medium 1 for the clustered substrate 20 (or 21) with electronic parts mounted will be explained referring to FIGS. 18 and 19.

In the embodiments described above, a method for preparing the case by applying resins to the clustered substrate and hardening them was explained. In this embodiment, a method for preparing the case of the electronic medium using a resin sheet will be explained.

When electronic parts are mounted on the second surface 20b (or 21b) of the clustered substrate 20 (or 21) as shown in FIG. 4 or FIG. 5, cover the second surface 20b (or 21b) of this clustered substrate 20 (or 21) with a resin sheet 36.

Then, clamp it with a plate 37 that is heated to above a softening temperature of the resin sheet 36. This will soften the resin sheet 36 and united with the clustered substrate 20 (or 21) in one unit. Then, complete the electronic medium 1 by cutting the electronic medium in a prescribed shape (the shape of individual electronic medium 1) from the unified clustered substrate 20 (or 21) with a cutter 29, etc.

In FIG. 19, the resin sheet 38 that is put over the clustered substrate 20 (or 21) is made uneven corresponding to the shapes (heights) of electronic parts mounted on the substrate. On a completed electronic medium 1 manufactured using such the resin sheet 38, it is possible to form a more flat outer surface.

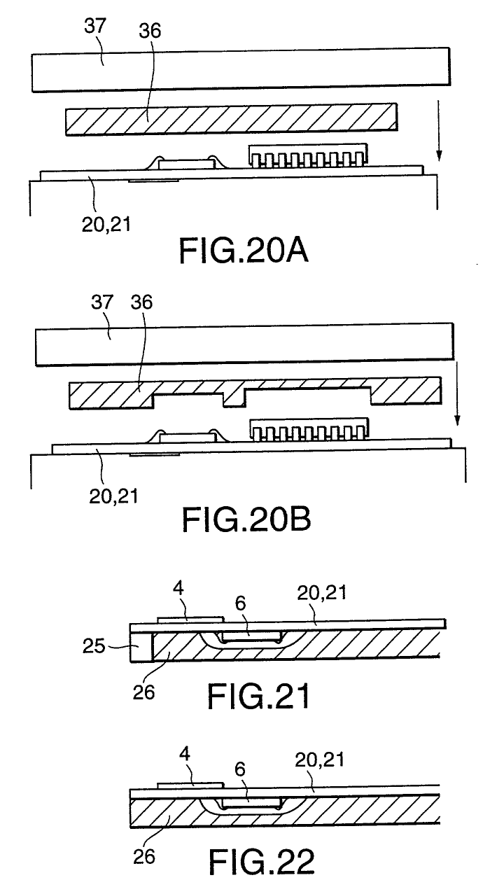

When the resin 38 is thus hardened, cut the electronic medium 1 in the prescribed shape (the shape of individual electronic medium 1 from the clustered substrate 20 (or 21) with a cutter 29, etc. Thus, the electronic medium 1 is completed. Further, a deformed example of the example shown in FIGS. 18 and 19 is shown in FIG. 20. The example shown in FIGS. 18 and 19 was explained according to a method for simultaneously manufacturing plural electronic media 1 using the clustered substrate. However, not restricted to this, this method has the same effect and is effective when manufacturing a single electronic medium as in the deformed example shown in FIG. 20. In FIG. 20, the method differs in that a single electronic medium is manufactured and the same parts are assigned with the same reference numerals as those shown in FIG. 18 and FIG. 19. Further, the finally completed electronic medium may be in a state that is cut in a specified size.

As shown in all the embodiments and deformed examples shown above, the external appearance and the sectional view of the final shape of the electronic medium 1 of this invention will be explained referring to FIGS. 21-24.

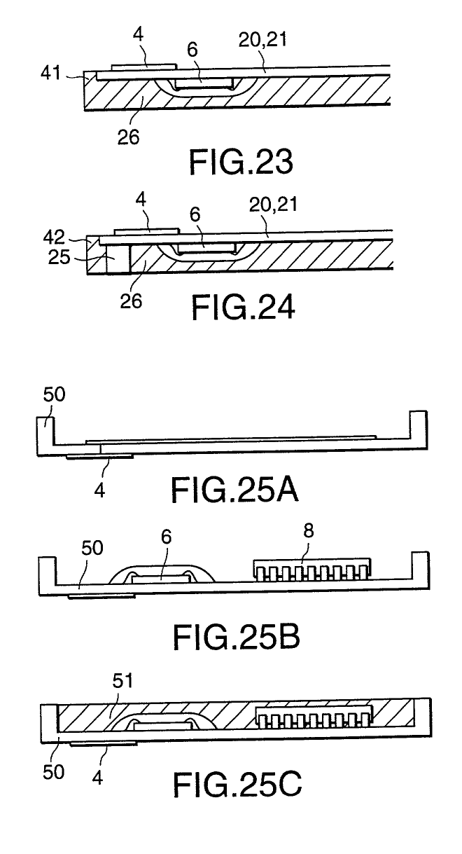

FIG. 21 shows the dam that is to dam up a coating/hardening resin at a prescribed position and is used as a frame of the electronic medium as it is. FIG. 22 shows the dam that is separated when the clustered substrate is cut to individual electronic media after the resin is hardened. Shown in FIG. 23 is a case using a substrate with slits formed shown in FIG. 5, wherein the periphery of the electronic medium and the ends of the contact pads are not the substrate but are formed with a resin. FIG. 24 shows a case using a substrate with the slits shown in FIG. 5 formed, wherein a dam is formed, coated with a resin and hardened. The periphery is formed with a resin not a substrate likewise the case shown in FIG. 23. However, as the dam is formed in the inside, the strength is increased more than the structure shown in FIG. 23.

Next, the method for manufacturing a single electronic medium individually will be explained referring to FIG. 25. As shown in FIG. 25A, in this embodiment a resin made case 50 formed with a resin without using a substrate is prewired for connecting electronic parts.

Then, as shown in FIG. 25B, after mounting various kinds of electronic parts on the resin made case 50, the inside of the resin made case 50 is coated with a resin 51. Hereinafter, an ultraviolet curing resin is used for this resin 51 in this embodiment. However, when a thermosetting resin is used, the same purpose and merit are achieved.

Then, the surface of the coated resin 51 is flattened using a transparent sheet and a roller or a squeegee.

The resin 51 that is processed flat is applied with ultraviolet rays to harden it as shown in FIG. 25C. When the resin 51 is hardened, the electronic medium 1 is completed.

In this embodiment, when a wired resin made case is used instead of a substrate, there are such merits that the entire electronic media can be manufactures similarly and strengths and characters of the entire electronic media can be made uniform.

As described above, according to the present invention, it is possible to provide more thin portable electronic media.

What is claimed is:

1. A portable electronic medium comprising:
a circuit substrate comprising a first surface that is exposed to the outside, forming one of the outer surfaces and a second surface provided at the back of the first surface with an electronic part mounted;
a terminal portion formed on the first surface to make the data exchange by connecting to an external device; and
a resin layer formed substantially in the same size as the circuit substrate, laminated on the entire second surface with the electronic part mounted, forming another outer surface.

2. A portable electronic medium according to claim 1, further comprising:
a protective layer provided to cover the surface of the resin layer.

3. A portable electronic medium according to claim 2, further comprising:
a print portion with prescribed information printed on the protective layer.

4. A portable electronic medium according to claim 1, wherein the resin layer includes:
a first resin layer laminated on at least a part of electronic part mounted on the second surface of the circuit board and the overall surface of the portion of the second surface without the electronic part mounted; and
a second resin layer laminated on the overall surface of the first resin layer and exposed to the outside, forming the outer surface.

5. A portable electronic medium according to claim 1, wherein the resin layer includes:
a first resin layer that has a first hardness and is laminated on at least a part of electronic part mounted on the second surface of the circuit substrate and the overall surface of the portion of the second surface without the electronic part mounted; and
a second resin layer that has a second hardness differing from the first harness of the first resin layer, is laminated on the overall surface of the first resin layer, and exposed to the outside forming the outer surface.

6. A portable electronic medium according to claim 1, wherein the resin layer includes:
a first resin layer that has a first hardness and is laminated on at least a part of electronic part mounted on the second surface of the circuit substrate and the overall surface of the portion without the electronic part mounted on the second surface; and
a second resin layer that has a second hardness which is softer than the first hardness of the first resin layer, is laminated on the overall surface of the first resin layer and exposed to the outside, forming the outer surface.

7. A portable electronic medium according to claim 4, wherein the second resin layer has a color differing from the color of the first resin layer.

8. A portable electronic medium according to claim 1, wherein the resin layer includes:
a first resin layer formed only at the peripheral portion of the second surface of the circuit substrate with the electronic part mounted; and
a second resin layer laminated on the inside of the first resin layer so as to cover all electronic part mounted on the second surface.

9. A portable electronic medium comprising:
a resin made case formed in a box shape;
a terminal portion formed on the bottom of the case for the data exchange by connecting to an external device;
a wiring portion formed inside the case and connected to the terminal portion;
an electronic part mounted in the inside of the case and connected to the wiring portion; and
a resin layer laminated on the entire inside portion of the case.

10. A manufacturing method of a portable electronic medium comprising a circuit substrate with the first surface exposed to the outside, forming one of the outer surfaces, the second surface provided on the back of the first surface with an electronic part mounted and a terminal portion formed on the first surface of the circuit board for the data exchange with an external device by connecting to the external device, comprising:
supplying a fused resin to cover the electronic part and the overall of the second surface; and
hardening the supplied resin.

11. A portable electronic medium manufacturing method, further comprising:
covering the overall surface of the resin supplied in the supply step with a covering material; and
flattening the surface covered by the covering material.

12. A portable electronic medium manufacturing method, further comprising:
removing the covering material after the resin is hardened in the hardening step.

13. A portable electronic medium manufacturing method, further comprising:
printing prescribed information on the surface of the covering material exposed to the outside after the resin is hardened in the hardening step.

14. A portable electronic medium manufacturing method, further comprising:
flattening the surface that is exposed to the outer surface of the resin supplied in the supply step.

15. A manufacturing method of a portable electronic medium comprising a circuit substrate with the first surface exposed to the outside, forming one of the outer surfaces and the second surface provided on the back of the first surface with an electronic part mounted and a terminal portion formed on the first surface of the circuit substrate for the data exchange by connecting to an external device, comprising:
a first supplying step for supplying a first fused resin to all portions of the second surface other than the portions with the electronic part mounted;
a first hardening step for hardening the first fused resin supplied in the first supplying step;
a second supplying step for supplying a second fused resin to the overall surface of the first resin hardened in the first hardening step; and
a second hardening step for hardening the second fused resin supplied in the second supplying step.

16. A portable electronic medium manufacturing method according to claim 15, wherein
the second supplying step is for supplying a second fused resin in hardness differing from the first fused resin on the resin hardened in the first hardening step.

17. A portable electronic medium manufacturing method according to claim 15, wherein
the second resin supplying step is for supplying a second fused resin in hardness that is softer than the hardness of the first fused resin on the resin hardened in the first hardening step.

18. A portable electronic medium manufacturing method according to claim 15, wherein
the second supplying step is for supplying a second fused resin having a color differing from the color of the first fused resin on the resin hardened in the first hardening step.

19. A portable electronic medium manufacturing method according to claim 10, further comprising:
cutting the resin hardened in the hardening step to a size of the final shape.

20. A portable electronic medium manufacturing method, further comprising:
cutting the resin hardened in the first and the second hardening steps to the size of final shape.
